(19) United States
(12) Patent Application Publication
(10) Pub. No.: US 2006/0172684 A1
(43) Pub. Date: Aug. 3, 2006

(54) Assembly structure of a blower

(75) Inventors: Alex Hong, Kaohsiung City (TW); Chao Han Chen, Kaohsiung City (TW)

Correspondence Address: BACON & THOMAS, PLLC, 625 SLATERS LANE, FOURTH FLOOR, ALEXANDRIA, VA, 22314, US

(73) Assignee: Sunonwealth Electric Machine Industry Co., Ltd., Kaohsiung City (TW)

(21) Appl. No.: 11/222,756

(22) Filed: Sep. 12, 2005

(30) Foreign Application Priority Data
Jan. 17, 2005 (TW) 094101324

(51) Int. Cl. H05K 5/00

(52) U.S. Cl. 454/184

(57) ABSTRACT

The present invention relates to an assembly structure of a blower, which includes a top cover and a base. The top cover provides an air inlet. The base is surrounded by a side wall and formed an air vent side. At least one first fastener set and one positioning set are disposed. The first fastener has a socket and a pin with lock. The positioning set has a positioning hole and a positioning pin. When assembling the top cover and the base, secure them at the right assembly position by the first fastener set and the engagement of the positioning pin and the positioning hole so as to avoid the looseness or resonance of the top cover. The design of the first fastener set disposes the socket in the side wall while the blower contour remain unchanged and the smoothness and air ventilation efficiency of air flow are not compromised.

### FIELD OF THE INVENTION

The invention relates to an assembly structure of a blower, which is disposed inside a notebook computer for dissipating the heat of the system to environment by virtue of the air circulation driven by the blades of the fan motor.

### BACKGROUND OF THE INVENTION

As shown in FIG. 1, the structure of the conventional blower includes a top cover 10, a base 20 and a fan motor 30, in which the top cover 10 is disposed an air intake 11, the base 20 is surrounded by a side wall along the perimeter and has an air vent side 21 formed on one side, and the fan motor 30 is disposed inside the base 20. After the top cover 10 is assembled with the base 20, both are fastened with a plurality of screws 12. Therefore, when the fan motor 30 rotates, air flow is entered from the air inlet 11 and blown off the air vent side 21 so as to dissipate the heat of the system to environment.

As the thickness of the top cover 10 of the above-mentioned blower is too thin to be formed by plastic injection due to the technical barrier, the top cover 10 is made of aluminum instead. This results in the limitation arising from the forming difficulty of aluminum and the space occupied by using plural screws 12 to fasten the top cover 10 and the base 20, which make the effective minimization of the contour of the blower that spares the space for other devices impossible.

Consequently, this brings about the second conventional blower as shown in FIG. 2. This conventional structure is also composed of a top cover 10, a base 20 and a fan motor 30, in which, likewise, the top cover 10 is equipped with an air inlet 11, the base 20 is surrounded by a side wall along the perimeter thereof and has an air vent side 21 formed on one side, and the fan motor 30 is disposed inside the base 20. As the thickness issue of the top cover 10 of the conventional blower is overcome by applying the composite material made from the PVC and PC polymer, the top cover can be manufactured by means of plastic injection, making the design of the overall contour of the blower more flexible at the same time.

However, these two conventional structures present one distinction in that a fastener is used by the latter structure to fix the top cover 10 and the base 20. The socket 22 are disposed along the perimeter of the base 20, the top cover is disposed the pin with lock 13 and the pin with lock 13 can be corresponded to and engaged with the socket 22.

In contrast to the former structure, the fastener in the second conventional blower saves more space than the screw in the first conventional blower, and the assembly and disassembly thereof is also easier. However, this gives rise to an issue of the loose top cover. Regardless of the socket or the pin with lock, as both have their respective mismachining tolerances and the deformations allowed for the injected product, a gap must be presented between the socket and the pin with lock. Whereas, the cause of the loose top cover is attributable to the gap, and the high-frequency vibration arising from the rotation of the fan motor will cause the noise generated by the resonance of the top cover.

Besides, as shown in FIG. 3, for sake of disposing the socket 22, the thicknesses of both side walls beside the air vent side 21 of the second conventional blower shall be augmented. Furthermore, given the constraint that the contour and shape of the blower must match with the blower and thus they are not subject to change, the only measure is to diminish the internal space of the blower. As a result, the recesses formed where the sockets 22 on both sides of the air vent side 21 are disposed result in the turbulent flow between the walls after air flow passes the sockets and affect the smoothness and the efficiency of the air flow evacuated by the fan.

As such, if the loose top cover and the resonance issue of the blower need to be completely resolved and the smoothness and the air ventilation efficiency for the air vent channel of the blower ought to be enhanced, the improvement to the assembly structure of the blower is undoubtedly on top of the list.

### SUMMARY OF THE INVENTION

Accordingly, the invention provides an assembly structure of a blower, which is shown in FIG. 4 and contains a top cover 10, a base 20 and at least a first fastener set and a positioning set disposed between the top cover and the base, to totally resolve the shortcomings of the foregoing two conventional structures.

The invention is mainly characterized by the inclusion of a pin with lock 13 disposed on the top cover 10 and a socket 25 disposed on the base, wherein the socket 25 is located on the side walls 23 beside the air vent side 21, the pin with lock 13 is located on the top cover 10 and corresponds to the location of the socket 25. Moreover, the pattern design of the pin with lock 13 and the socket 25 and space layout are arranged so that the socket 25 is directly disposed on the side wall 23 under the premise that the efficiency of the air evacuated by the blower is not affected while the contour of the blower remains the same in the meantime.

In addition, the positioning set has a positioning hole 29 in the proximity of the socket 25 on the top edge of the side wall 23 of the base and a projected positioning pin 15 on the top cover corresponding to the positioning hole 29. By means of the design of the positioning pin 15 and the positioning hole 29, the top cover 10 and the base 20 are always correctly positioned for an assembly free from looseness or resonance.

### BRIEF DESCRIPTION OF THE DRAWINGS

FIG. 1 is a 3D schematic view showing the appearance of the first conventional structure;

FIG. 2 is an 3D exploded schematic view showing the second conventional structure;

FIG. 3 is a 2D schematic view showing the second conventional structure;

FIG. 4 is a 3D exploded schematic view of the present invention;

FIG. 5 is a partial cross-sectional schematic view (I) of the present invention;

FIG. 6 is a partial cross-sectional schematic view (II) of the present invention;

FIG. 7 is a partial cross-sectional schematic view (III) of the present invention; and

FIG. 8 is a 2D schematic view of the present invention.

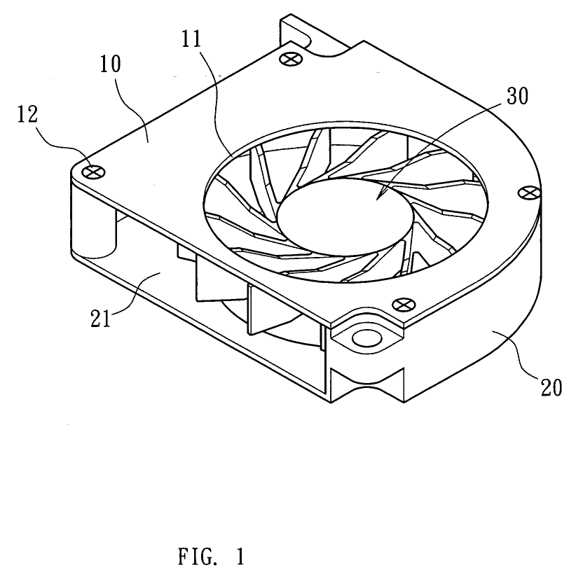

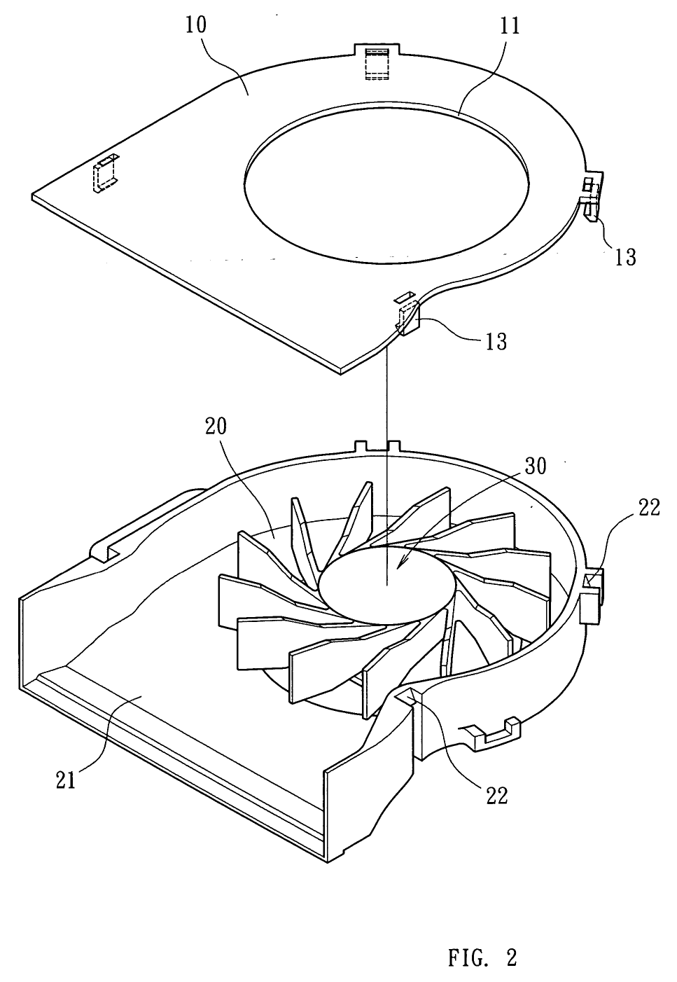

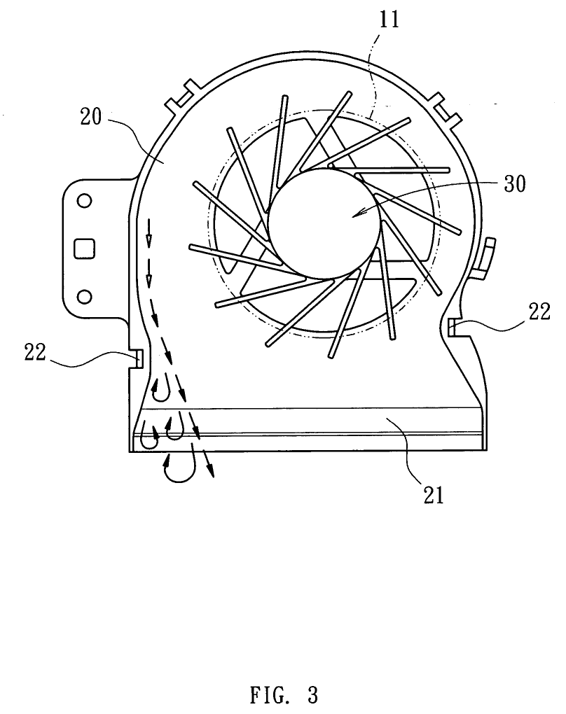

### DETAILED DESCRIPTION OF THE PREFERRED EMBODIMENT

The invention relates to an assembly structure of a blower, which is adopted to dissipate the heat of a computer system to environment. Here is the preferred embodiment in the following illustrative of the relevant positions of all parts in the present invention.

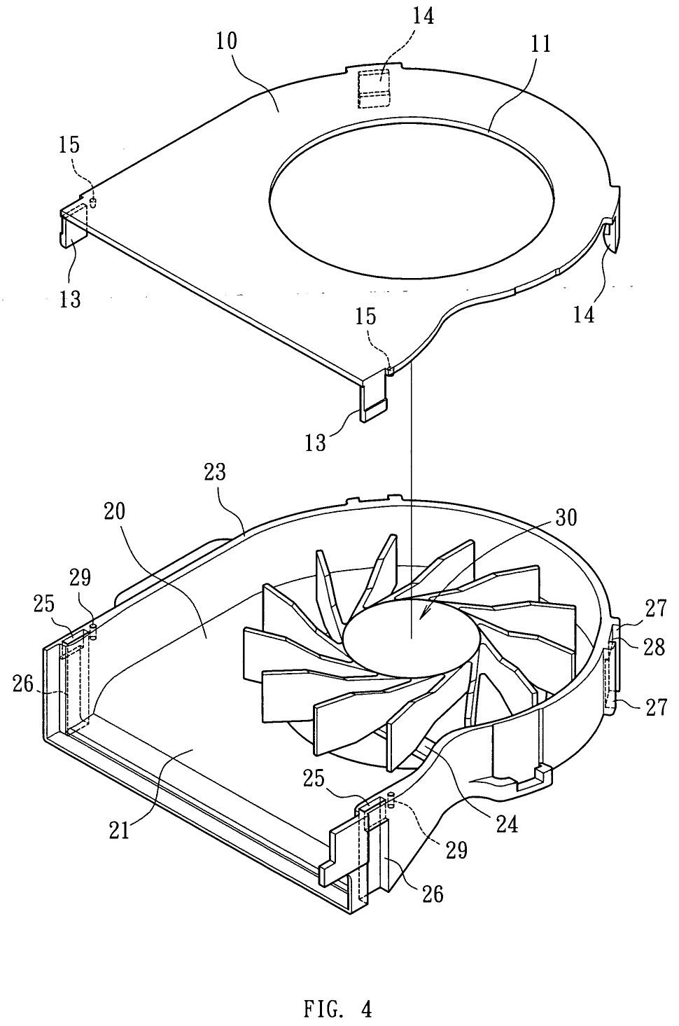

Please refer to FIG. 4 showing the blower of the present invention, which is composed of a top cover 10, a base 20 and a fan motor 30.

The top cover 10 and the base are in a form that mutually matches. The top cover 10 is equipped with an air inlet 11, the base 20 is surrounded by a side wall with one side thereof forming an air vent side 21, a motor seat 24 is disposed in the base 20, the fan motor 30 is disposed on the motor seat 24, and a plurality of blades extending beyond the exterior surface fan motor 30 can activate the air flow circulation.

There is at least one first fastener set, one second fastener set one and positioning set.

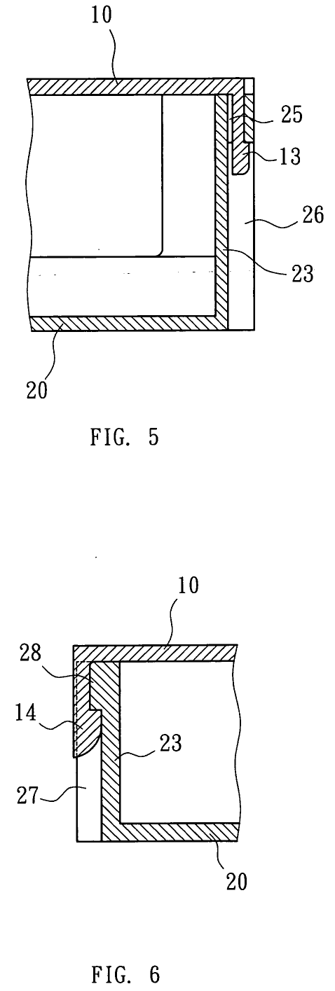

As shown in FIG. 4 and FIG. 5, the first fastener set of the preferred embodiment disposed on the side wall 23 beside the air vent side 21 contains a socket 25, which is disposed on the top edge of the side wall 23, and a slot 26, which is located beneath the socket 25 and slotted across the outside part of the side wall 23, thereby forming a channel through the socket 25 and the slot 26; in addition, a pin with lock 13 is protruded beyond a position of the top cover 10 where corresponds to the socket 25 and is mutually engaged with the socket 25.

As shown in FIG. 4 and FIG. 6, the second fastener set of the preferred embodiment disposed on the external circumferential surface of the side wall 23 of the base 20 contains two guide strips, which are vertically disposed, mutually parallel and are protruded beyond the external circumferential surface of the side wall 23, and a block 28, which is disposed on the top edge between the two guide strips 27. In addition, the top cover 10 at which the block 28 is located has a projected pin with lock 14 and the pin with lock 14 is mutually engaged with the block 28.

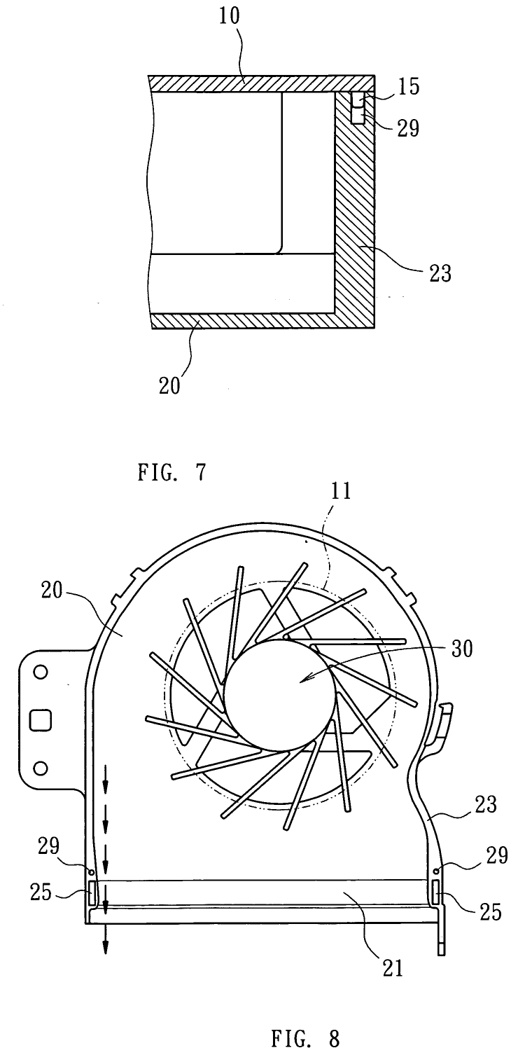

As shown in FIG. 4 and FIG. 7, the positioning set of the preferred embodiment disposed at a position adjacent to the first fastener set contains a positioning hole 29 where is located on the top edge of the side wall 23 of the base 20 and is in the proximity of the socket and a projected positioning pin 15 where corresponds to the positioning hole 29 and is mutually engaged with the positioning hole 29.

In sum, while assembling the top cover 10 and the base 20 of the present invention, on the first hand, the first and second fastener sets are used to fasten the top cover 10 and the base 15 together as a whole, and on the other hand, by means of the positioning design, the positioning pin 15 and the positioning hole 29 of the positioning set are used to firmly position the top cover 10 and the base 20 at the right assembling positions.

Moreover, FIG. 8 is a 2D schematic view of the present invention, in which the design of the socket 25 of the first fastener set in the present invention significantly reduces the space occupied by the socket 25 in the blower. As a consequence, the socket 25 of the first fastener set in the present invention can be directly disposed in the side wall 23 of the base 20 under the premise that the air vent channel at the air vent side 21 of the base 20 is not diminished and the smoothness and the efficiency of the air flow evacuated by the blower is not affected while the contour of the blower remains the same.

By means of the mentioned design, in addition to having the feature facilitating to assemble and disassemble, the assembly structure of the blower in the present invention outperforms the similar product in featuring that the top cover is firm, the air evacuation is smooth, the air ventilation efficiency is enhanced and the top cover is free from resonance. Therefore, the present invention not only has a novelty and a progressiveness, but also has an industry utility.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A assembly structure of a blower, comprising:
a top cover having an air inlet,
a base surrounded by a side wall and formed an air vent side; and
at least a first fastener set disposed between said top cover and said base, further comprising:
a socket disposed on a top side of said side wall;
a slot underneath said socket slotted externally across said side wall and connected with said socket; and
a first pin with lock disposed on said top cover so as to be engaged with said socket.

2. The assembly structure of a blower of claim 1, wherein at least a positioning set is disposed between said top cover and said base and further comprises a positioning pin located on said top cover and a positioning hole located on said base.

3. The assembly structure of a blower of claim 1, wherein said first fastener set is located in the proximity of said air vent side.

4. The assembly structure of a blower of claim 2, wherein said positioning hole is located on top of said side wall and is adjacent to said socket, and said positioning pin is located on a position of said top cover where corresponds to said positioning hole.

5. The assembly structure of a blower of claim 1, wherein at least a second fastener set is disposed between said top cover and said base and comprises two parallel guide strips protruded beyond an external circumferential surface of said side wall, a block is located on top of said guide strips and is between said guide strips, and a second pin with lock is located at a position where corresponds to said block and enables an engagement of said second pin with lock and said block.

6. The assembly structure of a blower of claim 1, wherein said base has a motor seat therein, a fan motor is disposed on said motor seat, said fan motor comprises a plurality of stators and a rotor, and a plurality of blades extended beyond an external circumferential surface of said rotor are used to circulate air flow.
